(19) United States
(12) Patent Application Publication
(10) Pub. No.: US 2024/0310466 A1
(43) Pub. Date: Sep. 19, 2024

(54) METHOD FOR CALIBRATING A MOTION DETECTION METHOD, LOCAL COIL, MAGNETIC RESONANCE APPARATUS AND COMPUTER PROGRAM PRODUCT

(71) Applicant: Siemens Healthineers AG, Forchheim (DE)

(72) Inventors: Johann Sukkau, Herzogenaurach (DE); Mario Bacher, Diepersdorf (DE); Peter Speier, Erlangen (DE)

(21) Appl. No.: 18/606,507

(22) Filed: Mar. 15, 2024

(30) Foreign Application Priority Data
Mar. 16, 2023 (EP) 23162376.0

(51) Int. Cl. G01R 33/58; G01R 33/565

(52) U.S. Cl. CPC G01R 33/58; G01R 33/56509

(57) ABSTRACT

A method for calibrating a motion detection method, to a local coil, a magnetic resonance apparatus and a computer program product. The motion detection method is configured for detecting motion of an object under examination during a magnetic resonance measurement by a magnetic resonance apparatus. First motion data of the object under examination is acquired in a capture period in accordance with the motion detection method. In addition, second motion data of the object under examination is acquired in the capture period in accordance with at least one other motion detection method. The motion detection method is calibrated using the first motion data and the second motion data.

### CROSS REFERENCE TO RELATED APPLICATIONS

This application claims the benefit of EP 23162376.0 filed on Mar. 16, 2023, which is hereby incorporated by reference in its entirety.

### FIELD

Embodiments relate to a method for calibrating a motion detection method, a local coil, a magnetic resonance apparatus and a computer program product.

### BACKGROUND

In the field of medical technology, magnetic resonance (MR) tomography, also known as magnetic resonance imaging (MRI), is characterized by high soft tissue contrasts. An object under examination, such as a patient, is typically positioned in a static, homogeneous magnetic field of an MR apparatus. During an MR measurement, radiofrequency (RF) transmit pulses are usually applied to the object under examination in accordance with an MR sequence. In conjunction with the static magnetic field, the generated transmit pulses excite nuclear spins in the object under examination, thereby triggering spatially encoded MR signals by gradient pulses. The MR signals are received by the MR apparatus and used to reconstruct MR images.

In order to achieve higher quality MR images, motion data is captured during the MR measurement, which data describes possible movement of the object under examination. This may be used, for example, to perform prospective or retrospective motion correction. Motion data may also be used to control, for example synchronize, the MR sequence with patient motion.

In recent years, for acquiring motion data, a technique using a pilot tone (PT) has been introduced and is described, for example, in the publications US 20160245888 A1, US 20170160364 A1 and US 20180353139 A1. Here, a PT signal is emitted by a PT generator, is modulated by motion of the object under examination, and received by an RF receive unit of the MR apparatus. The RF receive unit includes a receive bandwidth that is large enough to simultaneously receive the MR signal and PT signal that is not in the frequency range of the MR signal. The RF receive unit may comprise a plurality of receive elements, for example coil elements, each assigned to a receive channel.

For example, the received PT signal may be represented as a matrix whose matrix elements, for example the dimensions thereof, map the time and/or different receive channels of the PT signal. The PT signals of each receive channel may contain information on various motion components, such as respiratory motion and cardiac motion. PT sub-signals produced by the motion components may mix in the PT signal, for example linearly; this mixing of the PT sub-signals may be described for example by a mixing matrix. However, this mixing matrix is not known a priori, meaning that it must first be calibrated.

In addition to the PT technique, other motion detection methods are known, such as motion detection using MR navigators and/or a camera. Other motion detection methods of this kind are also calibrated in order to improve motion detection, for example with regard to the accuracy thereof.

### BRIEF SUMMARY AND DESCRIPTION

The scope of the present disclosure is defined solely by the claims and is not affected to any degree by the statements within this summary. The present embodiments may obviate one or more of the drawbacks or limitations in the related art. Independent of the grammatical term usage, individuals with male, female or other gender identities are included within the term.

Embodiments provide a robust method for calibrating a motion detection method.

A method for calibrating a motion detection method (MDM) is provided where the MDM is suitable for detecting motion of an object under examination during a magnetic resonance measurement by a magnetic resonance apparatus. First motion data of the object under examination is captured, for example recorded and/or measured and/or acquired, in accordance with the MDM over a capture period. During capture of the first motion data, i.e. in the capture period, second motion data of the object under examination is also captured, for example recorded and/or measured and/or acquired, in accordance with at least one other movement detection method (OMDM). The MDM is calibrated, for example adapted and/or trained, using the first motion data and the second motion data.

The second motion data may be captured throughout the capture period and/or continuously and/or without significant pauses in the capture period.

The first and second motion data may be captured in a calibration phase, for example a learning phase. The calibration phase may last 10 to 20 seconds, for example. The first and second motion data may be captured simultaneously and/or in parallel.

The second motion data may be stored in a random-access memory (RAM) of the magnetic resonance apparatus.

The at least one OMDM may be a method different from the MDM. The at least one OMDM may be a method independent of the MDM. The generation of the second motion data may be based on a different physical process and/or a different interaction and/or a different principle from the generation of the first motion data. For example, any measurement errors of the MDM may be detected using the OMDM.

Calibrating the MDM using the first motion data and the second motion data may include identifying at least one disturbance period in the capture period (i.e. during capture of the first motion data and the second motion data) in which the motion of the object under examination exhibits a disturbance, wherein the MDM is calibrated taking into account the at least one disturbance period. For example, for the calibration, the first and/or second motion data that lie within the at least one disturbance period are taken into account in a different manner from that of the first and/or second motion data that lie outside the at least one disturbance period. At least one disturbance period may be identified using the second motion data.

For example, the first and second motion data are captured in a period between the times tᵢ and t_{f}; a disturbance begins at time t₁≥tᵢ and the disturbance ends at time t₂≤t_{f}. The MDM may then be calibrated taking into account the period from t₁ to t₂.

Identifying the at least one disturbance period may include identifying at least one motion deviation using the second motion data, for example at least one predetermined motion pattern in the second motion data.

For example, the second motion data may describe a motion amplitude that describes an amplitude of the motion of the object under examination. The at least one motion deviation may be defined, for example, by the motion amplitude exceeding a predetermined threshold value. For example, the threshold value may be defined relative to an average motion amplitude.

For example, the at least one predetermined motion pattern includes a motion pattern that describes an irregularity, for example a signal peak in the motion amplitude.

For example, the first motion data captured in the at least one disturbance period is ignored when calibrating the MDM. The MDM may be calibrated exclusively on the basis of the first motion data captured outside the at least one disturbance period.

For example, the first motion data that was captured in the at least one disturbance period is weighted differently from the other first motion data when calibrating the MDM.

A disturbance strength indicating the severity of the disturbance may be assigned to the at least one disturbance period in each case. For example, the first motion data captured in the at least one disturbance period is weighted according to the assigned disturbance strength when calibrating the MDM.

The first motion data may be modified, for example adapted and/or changed, using the second motion data. The MDM may be calibrated using the modified first motion data.

When the first motion data is modified using the second motion data, corrupted first motion data, caused for example by any measurement errors, is removed from the first motion data. Corrupted first motion data may be caused, for example, by one or more unintentional movements of the object under examination. The modified first motion data is motion data that has been cleaned of measurement errors. The calibration of the MDM may be performed more reliably using such modified first motion data.

For example, modifying the first motion data includes removing the first motion data within the at least one disturbance period from the first motion data. With reference to the above example, for example first motion data captured in the period from t₁ to t₂ may be removed from the first motion data.

The motion of the object under examination may include at least two motion components, for example two motion components.

For example, a motion component is assigned to a specific type of motion. A plurality of types of motion may occur simultaneously in the body of the object under examination, for example cardiac motion, respiratory motion, and other voluntary or involuntary movements of the patient, for example turning the head, moving the hand, or legs, etc. The calibrated MDM may be used for example to extract at least one of the at least two motion components from motion data captured, for example, in a measurement phase following the calibration phase in accordance with the MDM.

To calibrate the MDM, PT signals for example are captured as the first motion data in the calibration phase. The object under examination, for example the patient, should breathe as normally as possible during the calibration phase. Using the captured first motion data, an unmixing solution may be calculated that is suitable for separating the at least two motion components. A motion component of the at least two motion components may, for example, be a respiratory motion, a cardiac motion, a head movement, or movement of the patient's entire body. The calculation of the unmixing solution may be performed more accurately by taking into account the second motion data.

Calibrating the MDM includes calibrating a BSS algorithm (BSS: Blind Signal Separation) for separating the at least two motion components.

For example, the BSS algorithm includes an ICA algorithm (ICA: Independent Component Analysis) and/or a PCA algorithm (PCA: Principal Component Analysis), for example a cPCA algorithm (cPCA: complex Principal Component Analysis).

The at least two motion components may include a cardiac motion and/or a respiratory motion of the object under examination.

For example, cardiac motion may be any motion caused by a regular contraction of the heart muscle, whether in the heart itself or in other parts of the body affected by it, for example by arterial blood vessels. For example, respiratory motion may be defined as any motion caused by a regular filling or emptying of the lungs with air, whether in the chest and/or abdomen itself or in other parts of the body affected by it.

The application of an ICA algorithm provides that an unmixing matrix is calculated from a calibration portion of motion data, for example a PT signal. For example, the ICA algorithm may be applied to a plurality of motion data captured for example by different receive channels. An unmixing matrix separates signals of different motion types in the motion data. (If a signal of only one type of motion is to be extracted from the motion data, this may also be done using an unmixing vector).

For example, when it is applied to a PT signal, the unmixing matrix separates at least one specific motion type, for example including the cardiac component, from other possible signal components. Depending on the implementation of the ICA algorithm, the unmixing matrix may be either complex or real-valued. With regard to further possible aspects of the ICA algorithm or the PCA algorithm, reference is made to publication EP3413076A1.

The second motion data may be captured using at least one sensor, for example a motion sensor. The second motion data may be captured using at least one sensor that is co-moved with the motion of the object under examination, for example by a chest motion of the object under examination.

For example, the second motion data describes a position of the at least one sensor in relation to the magnetic resonance apparatus, for example to a magnetic field, for example the main magnetic field (B0 field) and/or a gradient magnetic field of the magnetic resonance apparatus, and/or the acceleration of the at least one sensor.

For example, the second motion data is captured using at least one sensor that is disposed in or on a component of the magnetic resonance apparatus attached to the object under examination, for example a local coil, that is co-moved by the motion of the object under examination, for example by a chest motion of the object under examination.

For example, the second motion data describes a position of the local coil in relation to the magnetic resonance apparatus, for example to the main magnetic field of the magnetic resonance apparatus, and/or the acceleration of the local coil.

The at least one sensor may include a magnetic field sensor, for example a Hall sensor, for example a 3D Hall sensor, and/or an accelerometer and/or a gyro sensor.

A Hall sensor generates at least part of the second motion data by moving in the magnetic field of the magnetic resonance apparatus. A Hall sensor (also Hall probe or Hall encoder, named for Edwin Hall) uses the Hall effect to measure magnetic fields. Particularly outside the field of view (FOV), especially outside any tunnel (bore) of the magnetic resonance apparatus, the spatial distribution of the magnetic field is inhomogeneous but known, so that the physical position of the Hall sensor may be determined by the strength of the magnetic field measured by the Hall sensor.

The second motion data, for example translation data and/or rotation data, may be at least partially captured outside a bore of the magnetic resonance apparatus.

Translation data (for example x, y and/or z data) and/or rotation data (for example roll, pitch and/or yaw data) may be captured as second motion data by a Hall sensor outside the bore due to the usually strong inhomogeneity of the main magnetic field in this area. An angular velocity may also be calculated by time-dependent detection of rotational motion by the Hall sensor.

In addition, second motion data may be captured by measuring a gradient magnetic field using magnetic field sensors. Such a measurement may take place inside the bore in which the gradient magnetic field is generated. In this regard, reference is made to the publication US 20100176809A1 that shows how spatial locating of a local coil is carried out by a number of magnetic field sensors for measuring a gradient magnetic field.

An accelerometer (also acceleration sensor, vibration sensor or oscillation sensor) is a sensor that measures its acceleration. The accelerometer provides acceleration values in three spatial directions.

A gyro sensor is configured to measure angular velocities. A gyro sensor may advantageously be used to separate a dynamic acceleration caused by the motion of the object under examination or the accelerometer and a static acceleration caused by the earth's gravity.

The at least one sensor includes a plurality of sensors, each based on a different physical interaction for detecting the motion of the object under examination. For example, the plurality of sensors each provide a portion of the second motion data. The at least one sensor is based on a different interaction from that of the MDM for detecting the motion of the object under examination. For example, a PT method as MDM is based on an electromagnetic interaction of a PT field with conductive tissue, whereas a Hall sensor is used to measure a magnetic field, for example a main magnetic field of the magnetic resonance apparatus, or an accelerometer is used to measure an acceleration. A redundancy of the sensor data may be achieved by combining a plurality of sensors—for example a Hall sensor, an accelerometer and a gyro sensor.

For example, the magnetic field sensor, for example the Hall sensor, and the accelerometer are based on different physical interactions for detecting the motion of the object under examination. This enables the calibration of the MDM, for example the identification of at least one disturbance period, to be more robust.

For example, the respective motion data of the different sensors may be correlated with each other in order to provide more reliable evaluation of the second motion data.

The MDM may include an interaction of a pilot tone signal with the moving object under examination. The MDM may be a PT method. Here, a PT signal is emitted using a PT generator, is modulated by a motion of the object under examination, and is detected by the magnetic resonance apparatus. The magnetic resonance apparatus includes a receive bandwidth that is large enough to simultaneously receive an MR signal and a PT signal that is not within the frequency range of the MR signal. The magnetic resonance apparatus may include a plurality of receive elements, for example coil elements, each of that is assigned to a receive channel.

For example, the received PT signal may be represented as a matrix whose matrix elements map the time and/or different receive channels of the PT signal. The PT signals of each receive channel may contain information from various motion components, such as respiratory motion and cardiac motion. PT sub-signals generated by the motion components may mix in the PT signal, for example linearly; this mixing of the PT sub-signals may be described for example by a mixing matrix. The mixing matrix may be defined for example by the geometry and sensitivity of the coil elements. Calibrating the MDM using the first motion data and the second motion data advantageously involves calibrating the mixing matrix. For example, an unmixing matrix is determined using the first motion data and the second motion data.

In an embodiment, the method further includes: checking, on the basis of the second motion data, whether the motion of the object under examination in the capture period corresponds to at least one predefined criterion, and if the check indicates that the motion of an object under examination in the capture period does not correspond to the at least one predefined criterion: repeat acquisition of further first and second motion data and calibration of the MDM using the further first and second motion data.

The at least one predefined criterion may, for example, specify that the motion of an object under examination is sufficiently regular during the capture period. For example, the at least one predefined criterion may specify that the period of time in the capture period in which the motion of an object under examination is sufficiently regular, for example, does not exceed a predefined threshold value. Such a threshold value may, for example, be a particular amplitude of the motion of the object under examination (for example an absolute motion in the unit “cm”) and/or a particular acceleration. A very deep breath of the patient may be detected by the amplitude criterion. The acceleration criterion may advantageously be used to detect coughing or sneezing of the patient. Such criteria may also be combined.

The checking may provide that the quality and/or quantity of the captured first motion data is sufficient to (successfully) calibrate the MDM.

Time periods compromised by motion may be identified and the first motion data lying within these time periods to be removed. If the resulting first motion data still contains sufficient data, this obviates the need for repeat acquisition of further first and second motion data.

Embodiments further provide a local coil including at least one sensor for detecting second motion data in order to carry out a method as described above. In addition, a magnetic resonance apparatus is provided, for example having such a local coil, that is configured to carry out a method as described above.

The local coil and the magnetic resonance apparatus include aspects that correspond to the aspects of the proposed method for calibrating a motion detection method, that are set out in detail above. Features, advantages or alternative embodiments mentioned herein may also be applied to the other claimed objects and vice versa.

In addition, a computer program product is provided that includes a program and may be directly loaded into a memory of a programmable system control unit of a magnetic resonance apparatus and includes program code, for example libraries and auxiliary functions, for carrying out a proposed method when the computer program product is executed in the system control unit of the magnetic resonance apparatus. The computer program product may include a software with a source code that still needs to be compiled and linked or that only needs to be interpreted, or an executable software code that only needs to be loaded into the system control unit for execution.

The computer program product provides for the proposed method to be executed quickly and in an identically repeatable and robust manner. The computer program product may be configured such that it may carry out the proposed method steps using the system control unit. The system control unit includes the respective prerequisites, such as an appropriate working memory, an appropriate graphics card, or an appropriate logic unit, so that the respective method steps may be executed efficiently.

The computer program product is, for example, stored on a computer-readable medium or stored on a network or server, from where it may be loaded into the processor of a local system control unit that may be directly connected to the magnetic resonance apparatus or may be configured as part of the magnetic resonance apparatus. In addition, control information of the computer program product may be stored on an electronically readable data carrier. The control information of the electronically readable data carrier may be designed such that it carries out a proposed method when the data carrier is used in a system control unit of a magnetic resonance apparatus.

Examples of electronically readable data carriers are a DVD, a magnetic tape or a USB stick on which electronically readable control information, for example software, is stored. If this control information is read from the data carrier and stored in a system control unit of the magnetic resonance apparatus, all the embodiments of the method described above may be carried out.

Further advantages, features and details are described below and in the accompanying drawings. Corresponding parts are provided with the same reference characters in all the figures.

### BRIEF DESCRIPTION OF THE FIGURES

FIG. 1 schematically depicts a magnetic resonance apparatus according to an embodiment.

FIG. 2 schematically depicts a method for calibrating a motion detection method according to an embodiment.

FIGS. 3 and 4 depict representations of second motion data according to an embodiment.

### DETAILED DESCRIPTION

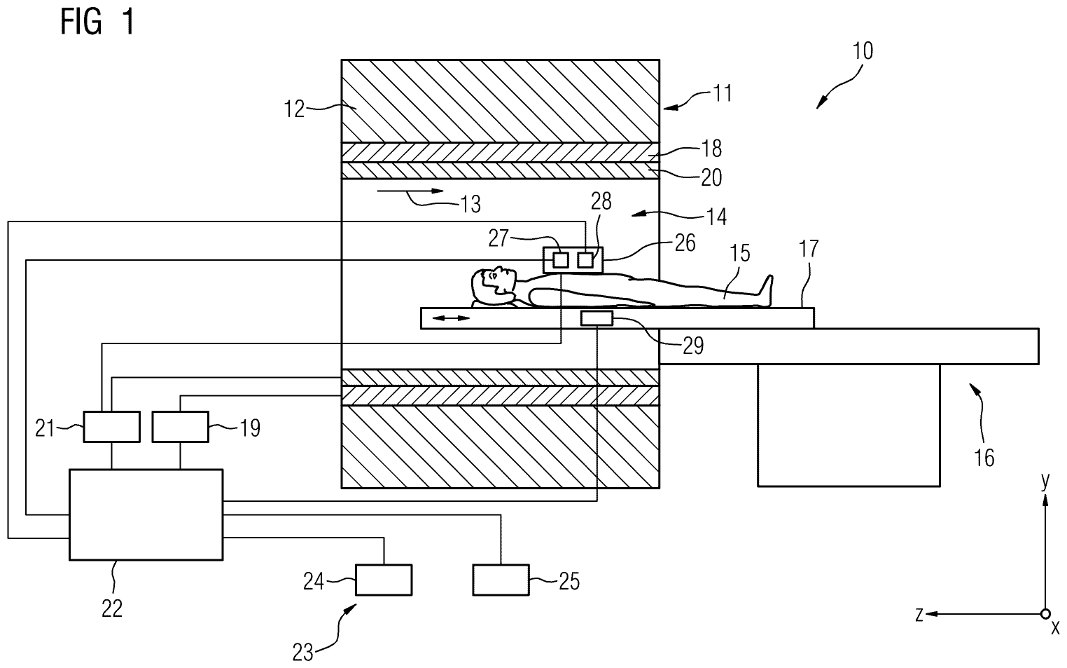

In FIG. 1, a magnetic resonance apparatus 10 is shown in schematic form. The magnetic resonance apparatus 10 includes a magnet unit 11, that includes a main magnet 12 for generating a powerful and, for example, temporally constant main magnetic field 13, also known as a B0 field. In addition, the magnetic resonance apparatus 10 includes a patient receiving area 14, for example in the form of a bore, for accommodating a patient 15 as an object under examination. The patient receiving area 14 in this embodiment is cylindrical in shape and is cylindrically enclosed by the magnet unit 11 in a circumferential direction. In principle, however, a different design of the patient receiving area 14 may be used. The patient 15 may be slid into the patient receiving area 14 by a patient positioning device 16 of the magnetic resonance apparatus 10. For this purpose, the patient positioning device 16 includes a patient table 17 designed to be movable within the patient receiving area 14.

In addition, the magnet unit 11 includes a gradient coil unit 18 for generating a gradient magnetic field that is used for spatial encoding during imaging. The gradient coil unit 18 is controlled by a gradient control unit 19 of the magnetic resonance apparatus 10. The magnet unit 11 also includes a radiofrequency antenna unit 20 which in this exemplary embodiment is designed as a body coil permanently incorporated in the magnetic resonance apparatus 10. The radiofrequency antenna unit 20 is controlled by a radiofrequency antenna control unit 21 of the magnetic resonance apparatus 10 and applies RF excitation pulses into an examination space constituted essentially by a patient receiving area 14 of the magnetic resonance apparatus 10. This causes the main magnetic field 13 generated by the main magnet 12 to excite atomic nuclei. Magnetic resonance signals are generated by relaxation of the excited atomic nuclei. The radiofrequency antenna unit 20 is designed to receive the magnetic resonance signals and thus forms part of an RF receive unit of the magnetic resonance apparatus.

The magnetic resonance apparatus 10 additionally includes, for example as part of the radiofrequency antenna unit 20, a local coil 26 that is disposed on the chest of the patient 15. The local coil 26 may, for example, be strapped to the patient 15 with belts. Such a local coil 26 is, for example, a body array coil with a plurality of coil elements. The local coil 26 is thus a component of the magnetic resonance apparatus attached to the patient 15 and is co-moved by the motion of the patient 15, for example by motion of the patient's chest. The local coil 26 is configured to receive the magnetic resonance signals. The local coil 26 is mounted in the vicinity of the region of the patient 15 that is to be imaged by a magnetic resonance measurement. The magnetic resonance signals generated in this region may thus be captured with a particularly high signal-to-noise ratio. The local coil 26 may be configured to transmit RF excitation pulses.

The magnetic resonance apparatus 10 includes a system control unit 22 for controlling the main magnet 12, the gradient control unit 19 and for controlling the radiofrequency antenna control unit 21. The system control unit 22 centrally controls the magnetic resonance apparatus 10, such as for example the execution of a magnetic resonance sequence. The system control unit 22 also includes an evaluation unit (not shown in detail) for evaluating the magnetic resonance signals that are captured during the magnetic resonance examination. In addition, the magnetic resonance apparatus 10 includes a user interface 23 that is connected to the system control unit 22. Control information, such as imaging parameters, as well as reconstructed magnetic resonance images may be displayed on a display unit 24, for example on at least one monitor, of the user interface 23 for medical personnel. In addition, the user interface 23 includes an input unit 25 by which information and/or parameters may be entered by medical personnel during a measurement process.

To perform a (first) motion detection method to be calibrated, the PT method, the magnetic resonance apparatus further includes a pilot tone generator 29 that is here disposed in the patient table 17. The PT method is an electromagnetic, non-contact motion detection method. According to this method, the PT generator emits a PT signal that is modulated by a motion of the patient 15 and is detected by the RF receive unit of the magnetic resonance apparatus 10, for example by the local coil 26, as first motion data. Thus, this motion detection method involves an interaction of the PT signal with the moving patient 15. The PT generator 29 may be controlled, for example, by the system control unit 22. The local coil 26 includes a receive bandwidth that is large enough to simultaneously receive the magnetic resonance signal and PT signal that is not in the frequency range of the MR signal. The local coil 26 may include a plurality of receive elements, for example coil elements, each associated with a receive channel.

The local coil 26 includes a magnetic field sensor in the form of a Hall sensor 27 and an accelerometer 28 with which second motion data may be captured in accordance with other motion detection methods. The magnetic resonance apparatus may also include further sensors for acquiring second motion data, such as a gyro sensor. The sensors 27, 28 are here incorporated in the local coil 26, for example. The sensors 27, 28 are co-moved with the local coil 26 by the motion of the object under examination, for example by the motion of the chest of the patient 15. For example, in examinations of the heart and/or the abdomen and/or the patient's chest, a mechanical connection of the sensors 27, 28 with the chest motion may be established in this way.

The sensors 27, 28 may be used to capture second motion data, for which reason the sensors 27, 28 may be referred to as motion sensors. The Hall sensor 27 and the accelerometer 28 are based on different physical interactions for detecting the motion of the patient 15. While the Hall sensor 27 interacts with the main magnetic field 13 and the signal generation is therefore based on a magnetic force, the signal generation of the accelerometer 28 is based on the inertial force.

In FIG. 1, the sensors 27, 28 are disposed inside the bore of the magnetic resonance apparatus. However, the acquisition of the second motion data by the sensors 27, 28 may also take place completely or partially outside the bore.

Inside the bore, the main magnetic field 13 is usually very homogeneous, so that the resolution of a typical Hall sensor (for example 0.1 mT) is usually insufficient to detect typical field inhomogeneities (for example 500 nT). Therefore, translation coordinates (for example x, y, z) cannot usually be readily determined in the bore. Particularly in the case shown in FIG. 1, for example, in which the local coil 26 is wrapped around the patient 15, there are usually no major translational motions of the sensors 27, 28 for example due to breathing and/or coughing of the patient 15; such motions are usually no more than a few centimeters. However, in addition to the translational component, such motions usually also include a rotational component, i.e. rotational movements such as turning, tilting and/or inclination. Such rotational motions may be determined very precisely as second motion data. The homogeneous main magnetic field 13 usually includes only one non-zero component B0_{z} in the bore. The components B0ₓ and B0_{y} are usually zero. A proportion of the rotational motion of the coil may therefore be calculated from the changed motion data Hallₓ, Hall_{y}, Hall_{z} of the Hall sensor: Hallₓ, Hall_{y}, Hall_{z} also change as projections of the magnetic field component B0_{z} in the homogeneous main magnetic field 13 of the bore.

The sensors 27, 28 transmit the captured second motion data to the system control unit 22 for further evaluation.

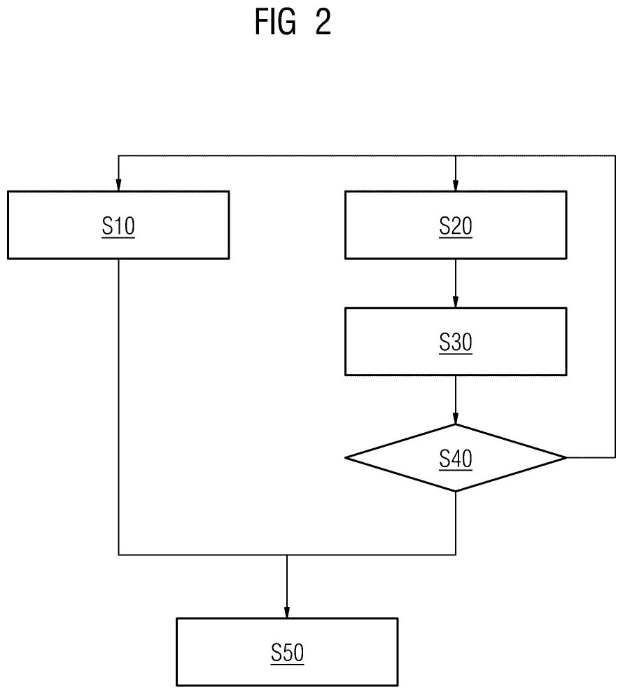

FIG. 2 depicts a method for calibrating a motion detection method, such as the PT method explained above. In S10, first motion data of the patient 15 is captured in accordance with the motion detection method to be calibrated. In S20, during the acquisition of the first motion data, second motion data of the patient 15 is captured in accordance with at least one other motion detection method, for example by the Hall sensor 27 and/or the accelerometer 28. The second motion data describes for example the position of the local coil 26 with respect to the main magnetic field 13 and its acceleration.

The time period of S10 and S20 may be regarded as a learning phase. The second motion data captured in this learning phase is stored for example in a memory module, for example a RAM, of the system control unit.

In S50, the motion detection method to be calibrated is calibrated using the first and second motion data captured in S10 and S20. For this purpose, at least one disturbance period that occurred during the acquisition of the first motion data and the second motion data may be identified beforehand in S30 using the second motion data. In the at least one disturbance period, the motion of the object under examination exhibits a disturbance.

For example, on completion of the training phase in S10 and S20, the stored second motion data is analyzed in S30 in order to detect problematic motion patterns (for example sudden acceleration and position peaks due to coughing) that indicate a disturbance period.

In S40, the second motion data may be used to check whether the motion of the patient 15 in the capture period corresponds to at least one predefined criterion, for example whether it is sufficiently regular. If this is the case, calibration may be carried out in S50 without further ado. If this is not the case, S10, S20, S30 and S40 are carried out again.

In S50, the calibration of the motion detection method to be calibrated, for example the PT method, is then performed, taking into account the at least one disturbance period.

The motion of the chest of the patient 15 includes two motion components: cardiac and respiratory motion. For example, in each receive channel of the first motion data captured according to the PT method, the cardiac and respiratory motions are linearly mixed by an initially unknown mixing matrix. A BSS algorithm, for example an ICA algorithm and/or a PCA algorithm, that may be calibrated using the second motion data, may be used to separate respiratory and cardiac motion without additional information. These algorithms usually require a training data set of first motion data of about 10-20 seconds for their calibration, during which the patient should breathe normally in order to be able to determine an unmixing solution that separates cardiac and respiratory motion.

However, it is possible that the patient 15 will make involuntary movements during this training phase, such as coughing, twisting, hiccupping, etc. Such disturbances, for example motion deviations, may be identified in S30 using the second motion data and taken into account in S50.

For example, the quality of the first motion data may advantageously be inferred from the disturbances identified in S30. If the second motion data shows motion of the patient 15, it may be assumed that the first motion data captured over time, for example PT data, is not suitable for calibrating the motion detection method to be calibrated, for example the PT method.

If, for example, the second motion data indicates motion of the patient 15 that contaminates the first motion data in a sufficiently large part of the training phase, the training phase should be repeated, for example automatically. If the second motion data indicates that the first motion data is not motion-contaminated or only in a small part of the training phase, then these disturbance periods may be identified. The first motion data lying within these disturbance periods may be ignored during the calibration of the motion detection method to be calibrated, so that the calibration is only performed using the first motion data that lies outside the disturbance periods (i.e. is non-motion-contaminated). For example, the first motion data is modified by removing the first motion data within the disturbance periods, and the calibration in S50 is then performed using the modified first motion data. The training phase then does not need to be repeated, so that time may be saved.

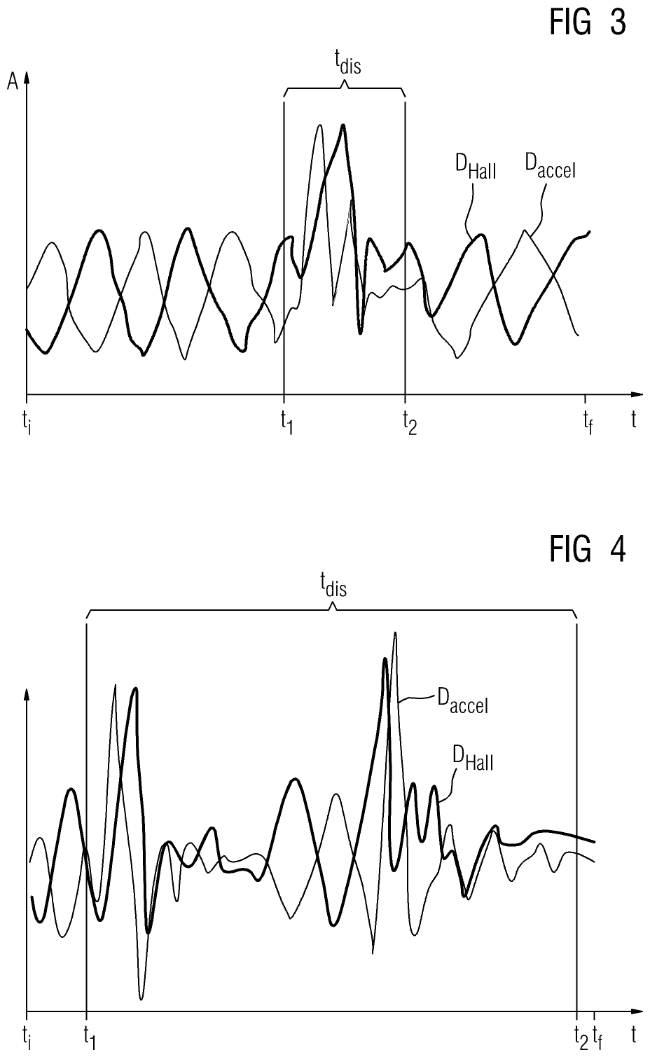

FIG. 3 and FIG. 4 depicts examples of second motion data as a function of time t. In each case, motion data D_{Hall} detected by the Hall sensor 27 is shown as a first part of the second motion data and motion data D_{accel} detected by the accelerometer 28 is shown as a second part of the second motion data. This second motion data may be used to check in S40 whether the training phase should be repeated.

The second motion data shown in FIG. 3 is only disturbed in a small interval t_{dis} of the training phase lasting from tᵢ to t_{f} by involuntary motion of the patient 15, so that the first motion data lying outside t_{dis} (i.e. from tᵢ to t₁ and from t₂ to t_{f}) is sufficient to calculate an unmixing solution. In this case, the training phase does not need to be repeated.

In contrast, most of the second motion data shown in FIG. 4 is contaminated by motion. In this case, the training phase must be repeated. The repetition is automatic, so that no interaction by the operator is required.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for calibrating a motion detection method that is configured to detect motion of an object under examination during a magnetic resonance measurement by a magnetic resonance apparatus, the method comprising:
capturing, using the motion detection method, first motion data of the object under examination in a capture period;
capturing, using at least one other motion detection method, second motion data of the object under examination in the capture period; and
calibrating the motion detection method using the first motion data and the second motion data.

2. The method of claim 1, wherein calibrating the motion detection method using the first motion data and the second motion data comprises:
using the second motion data to identify at least one disturbance period in the capture period in which the motion of the object under examination exhibits a disturbance, for example deviation, wherein the motion detection method is calibrated taking into account the at least one disturbance period.

3. The method of claim 2, wherein identifying the at least one disturbance period involves identifying at least one motion deviation based on the second motion data.

4. The method of claim 1, wherein calibrating the motion detection method using the first motion data and the second motion data comprises:
modifying the first motion data using the second motion data by removing the first motion data within the at least one disturbance period; and
calibrating the motion detection method using the modified motion data.

5. The method of claim 1, wherein the motion of the object under examination comprises at least two motion components, wherein calibrating the motion detection method involves calibrating a BSS algorithm for separating the at least two motion components.

6. The method of claim 5, wherein the BSS algorithm comprises an ICA algorithm and/or a PCA algorithm.

7. The method of claim 5, wherein the at least two motion components comprise a cardiac motion and a respiratory motion of the object under examination.

8. The method of claim 1, wherein the motion detection method comprises an interaction of a pilot tone signal with the moving object under examination.

9. The method of claim 1, further comprising:
checking, on the basis of the second motion data, whether the motion of the object under examination in the capture period corresponds to at least one predefined criterion; and
when the check shows that the motion of an object under examination in the capture period does not correspond to the at least one predefined criterion, further first and second motion data if acquired and the motion detection method is calibrated using the further first and second motion data.

10. The method of claim 1, wherein the second motion data is captured using at least one sensor which is co-moved by the motion of the object under examination.

11. The method of claim 10, wherein the motion comprises a chest motion of the object under examination.

12. The method of claim 1, wherein the second motion data is captured using at least one sensor which is disposed in or on a component of the magnetic resonance apparatus that is attached to the object under examination and that is co-moved by the motion of the object under examination.

13. The method of claim 1, wherein the motion comprises a chest motion of the object under examination.

14. The method of claim 13, wherein the at least one sensor comprises a magnetic field sensor, an accelerometer, or a gyro sensor.

15. The method of claim 13, wherein the at least one sensor comprises a plurality of sensors, each of which is based on a different physical interaction for detecting the motion of the object under examination.

16. A magnetic resonance apparatus, comprising:
a local coil configured to use a motion detection method to capture first motion data of an object under examination in a capture period, the local coil further configured to use at least one other motion detection method to capture second motion data of the object under examination in the capture period;
wherein the motion detection method is calibrated using the first motion data and the second motion data.

17. A non-transitory computer implemented storage medium, including machine-readable instructions stored therein for calibrating a motion detection method that is configured to detect motion of an object under examination during a magnetic resonance measurement by a magnetic resonance apparatus, the machine-readable instructions when executed by at least one processor, cause the processor to:
capture, using the motion detection method, first motion data of the object under examination in a capture period;
capture, using at least one other motion detection method, second motion data of the object under examination in the capture period; and
calibrate the motion detection method using the first motion data and the second motion data.
